(19) United States
(12) Patent Application Publication
(10) Pub. No.: US 2025/0385196 A1
(43) Pub. Date: Dec. 18, 2025

(54) SELECTIVE MAGNETIC ADHESION OF EMI GRIDS

(71) Applicant: Raytheon Company, Tewksbury, MA (US)

(72) Inventors: Raquel Ovalle-Robles, Sachse, TX (US); Catherine Trent, Allen, TX (US); Gary A. Frazier, Thermopolis, WY (US)

(21) Appl. No.: 18/744,258

(22) Filed: Jun. 14, 2024

(51) Int. Cl. H01L 23/552; H01L 21/56; H01L 23/31

(52) U.S. Cl. CPC H01L 23/552; H01L 21/56; H01L 23/3157

(57) ABSTRACT

A method includes positioning a grid onto a substrate that includes one or more bus bars on a top surface. The method also includes selectively applying magnetic particles to portions of a top surface of the grid. The method further includes applying a magnetic field to a bottom surface of the substrate, the magnetic field attracting the magnetic particles downward toward the substrate. In addition, the method includes applying an encapsulation layer over the grid while the magnetic field is applied to the bottom surface of the substrate.

### TECHNICAL FIELD

This disclosure is generally directed to magnetic adhesion. More specifically, this disclosure is directed to techniques for selective magnetic adhesion of electromagnetic interference (EMI) grids.

### BACKGROUND

Electromagnetic interference (EMI) protection technology can be optimized to increase optical transmission, reduce laser back scatter, and provide RF performance required for high-speed platforms. Additionally, coatings or encapsulation over an EMI protective layer can provide an anti-reflection characteristic that enhances optical performance as well as protection from damage by particle impact.

### SUMMARY

This disclosure is directed to techniques for selective magnetic adhesion of electromagnetic interference (EMI) grids.

In a first embodiment, a method includes positioning a grid onto a substrate that includes one or more bus bars on a top surface. The method also includes selectively applying magnetic particles to portions of a top surface of the grid. The method further includes applying a magnetic field to a bottom surface of the substrate, the magnetic field attracting the magnetic particles downward toward the substrate. In addition, the method includes applying an encapsulation layer over the grid while the magnetic field is applied to the bottom surface of the substrate.

In a second embodiment, a system includes a substrate. The system also includes one or more bus bars disposed on a top surface of the substrate. The system further includes a grid positioned on the substrate. The system also includes magnetic particles selectively applied to portions of a top surface of the grid. The system further includes a magnetic source configured to apply a magnetic field to a bottom surface of the substrate, the magnetic field configured to attract the magnetic particles downward toward the substrate. In addition, the system includes an encapsulation layer disposed over the grid and configured to be applied while the magnetic field is applied to the bottom surface of the substrate.

In a third embodiment, a method includes positioning a grid onto an annular substrate that includes a beveled edge portion on a top surface. The method also includes selectively applying magnetic particles to portions of a top surface of the grid covering the beveled edge portion of the annular substrate. The method further includes applying a magnetic field to a bottom surface of the substrate, the magnetic field attracting the magnetic particles downward toward the annular substrate. In addition, the method includes applying an encapsulation layer over the grid while the magnetic field is applied to the bottom surface of the annular substrate.

Other technical features may be readily apparent to one skilled in the art from the following figures, descriptions, and claims.

### BRIEF DESCRIPTION OF THE DRAWINGS

For a more complete understanding of this disclosure and its advantages, reference is now made to the following description taken in conjunction with the accompanying drawings, in which like reference numerals represent like parts:

FIG. 1 illustrates an example viewing window for which selective magnetic adhesion of an EMI grid can be employed, according to this disclosure;

FIGS. 2A through 2D illustrate an example process for selective magnetic adhesion of an EMI grid according to this disclosure;

FIG. 3 illustrates additional details of the process of FIGS. 2A through 2D according to this disclosure; and

FIG. 4 illustrates an example method for selective magnetic adhesion of an EMI grid according to this disclosure.

### DETAILED DESCRIPTION

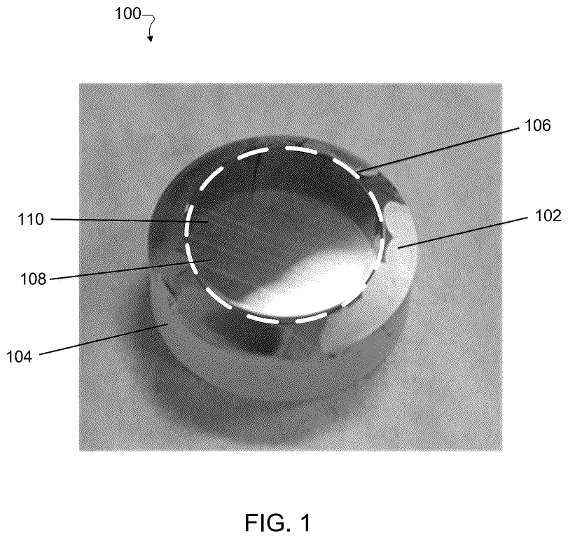

FIGS. 1 through 4, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

For simplicity and clarity, some features and components are not explicitly shown in every figure, including those illustrated in connection with other figures. It will be understood that all features illustrated in the figures may be employed in any of the embodiments described. Omission of a feature or component from a particular figure is for purposes of simplicity and clarity and is not meant to imply that the feature or component cannot be employed in the embodiments described in connection with that figure. It will be understood that embodiments of this disclosure may include any one, more than one, or all of the features described here. Also, embodiments of this disclosure may additionally or alternatively include other features not listed here.

As discussed above, the use of EMI protection technology, such as using an EMI mesh or grid, can be optimized to increase optical transmission, reduce laser back scatter, and provide RF performance required for high-speed platforms. Additionally, coatings or encapsulation over the EMI mesh can provide an anti-reflection characteristic that enhances optical performance as well as protection from damage by particle impact.

Some methods exist for attaching an EMI mesh to an optically transparent material. However, some existing methods can result in failed coatings due to contamination and/or in partial delamination during encapsulation. For example, one technique includes a virtual adhesion method in which magnetic particles or films are coated on the EMI mesh's surface. The structure is then submitted to a magnetic field to temporarily affix the EMI mesh to the substrate during the encapsulation process to permanently adhere the EMI mesh to the overall structure by coating.

In this existing technique, the magnetic particles or films may be coated on the entirety of the EMI mesh. In implementations where the structure is a viewing window, obscuration in the EMI field of view (i.e., the window viewing area) may occur due to the addition of the magnetic films or particles. For example, carbon nanotube (CNT) based EMI grids may be thinner than 2 microns. The addition of material (such as magnetic films or particles) to the EMI grid can directly affect the transmission of the EMI grid. Also, encapsulation issues can arise due to the additional magnetic films or particles. Thus, a technique is desired in which the field of view is not obscured and/or the encapsulation is not affected.

This disclosure provides techniques for selective magnetic adhesion of EMI grids. As discussed in greater detail below, the disclosed embodiments include a process for transferring or placing an EMI grid onto an optically transparent window without contamination, while supporting handling tasks, encapsulation, and edge integration. Note that while this disclosure is described with respect to viewing windows, it will be understood that the principles disclosed here are also applicable to other types of devices or environments.

FIG. 1 illustrates an example viewing window 100 for which selective magnetic adhesion of an EMI grid can be employed, according to this disclosure. As shown in FIG. 1, the viewing window 100 is shown in a perspective view and includes a beveled portion 102 disposed above a base portion or substrate 104. In some embodiments, both the beveled portion 102 and the substrate 104 are annular. In the center of the viewing window 100 is an optically transparent viewing area 106 that is surrounded by the beveled portion 102 and the substrate 104. The viewing area 106 and the beveled portion 102 are covered by an EMI grid 108. In some embodiments, the EMI grid 108 is a CNT based EMI grid that is approximately 250 nanometers in thickness, although other materials and dimensions are possible for the EMI grid 108. A coating or encapsulation layer 110 disposed over the EMI grid 108 can provide an anti-reflection characteristic that enhances optical performance of the viewing window 100 and also helps to protect the EMI grid 108 from damage by particle impact.

As discussed in greater detail below, the EMI grid 108 can be at least temporarily adhered to the surface of the viewing area 106 and the beveled portion 102 by a magnetic field. A technique is used to selectively pattern the EMI grid 108 with magnetic particles at the edges of the viewing window 100, such as within the beveled portion 102. This ensures that the adherence of the EMI grid 108 under the magnetic field occurs only at the edge of the viewing window 100, so as to avoid any contamination of the optical surface of the viewing area 106 and assist in tasks such as encapsulation or edge integration. This also helps to ensure that obscuration in the viewing area 106 from the magnetic particles is avoided. Similarly, encapsulation issues related to the introduction of particles in the viewing area 106 can be avoided.

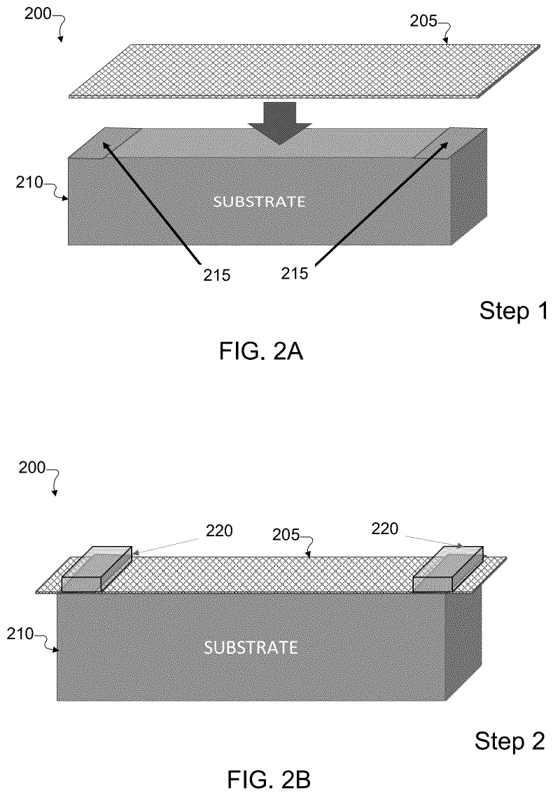

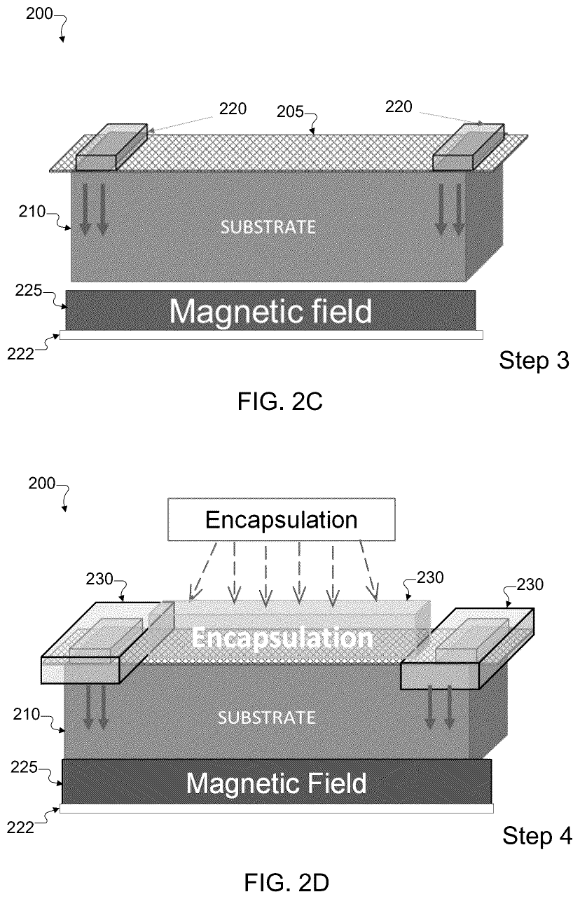

FIGS. 2A through 2D illustrate an example process 200 for selective magnetic adhesion of an EMI grid according to this disclosure. In some embodiments, the process 200 can be used to selectively pattern the EMI grid 108 with magnetic particles at the edges of the viewing window 100.

As shown in FIG. 2A, in step 1 of the process 200, an EMI grid 205 is positioned onto a substrate 210 that includes one or more bus bars 215 on a top surface. In some embodiments, the substrate 210 may be formed of zinc sulfide (ZnS) or another non-conductive optical material. The bus bars 215 may be formed of a conductive material and can serve as electrical contacts for the electrically conductive EMI grid 205. While the substrate 210 is shown as a rectangular block, this is merely for case of illustration. In some embodiments, the substrate 210 can represents the circular substrate 104 of FIG. 1, the EMI grid 205 can represent the EMI grid 108, and the bus bars 215 can be disposed on the beveled portion 102.

As shown in FIG. 2B, in step 2, a magnetic film or magnetic particles 220 are selectively applied to edge portions of the top surface of the EMI grid 205. In particular, the magnetic particles 220 can be applied to the edge portions of the EMI grid 205 that are over the bus bars 215. In some embodiments, the magnetic particles 220 can be applied by painting, spray painting, electro-static painting, electrochemically applying, pasting, or using any other suitable application technique. In some embodiments, the magnetic particles 220 may or may not be applied to other portions of the EMI grid 205. In some embodiments, the magnetic particles 220 can be additionally or alternatively applied to a set of locations on the substrate 210 that promotes selective integration between the EMI grid 205 and the substrate 210 at specific locations

As shown in FIG. 2C, in step 3, a magnetic source 222 (e.g., an electromagnet) applies a magnetic field 225 on the opposite (e.g., bottom) surface of the substrate 210 (e.g., underneath the substrate 210). The magnetic field 225 attracts the magnetic particles 220, and presses the magnetic particles 220 towards the substrate 210, as indicated by the arrows. This pressure from the magnetic particles 220 causes a downward force on the edges of the EMI grid 205, and essentially pinches the EMI grid 205 between the magnetic particles 220 and the bus bars 215 disposed under the EMI grid 205. This pinching force on the edges of the EMI grid 205 acts to keep the EMI grid 205 in place whenever the magnetic field 225 is applied.

As shown in FIG. 2D, in step 4, an encapsulation layer 230 is applied over EMI grid 205 while the magnetic field 225 is applied. Because the EMI grid 205 is kept in place while the magnetic field 225 is applied, the process of applying the encapsulation layer 230 does not disturb the position of the EMI grid 205. Thus, the EMI grid 205 can be encapsulated without any contaminating particles over the middle portion of the EMI grid 205, which can represent the optical surface of the viewing area 106 of FIG. 1. In addition to the encapsulation layer 230 covering the EMI grid 205, the encapsulation layer 230 can also cover some or all of the magnetic particles 220 on the edge portions of the EMI grid 205. Other processes, such as edge integration, edge masking, or edge termination, can be performed in step 4 without disturbing the position of the EMI grid 205, as long as the magnetic field 225 is applied.

In some embodiments, the EMI grid 205 can be removed without damaging the substrate 210 by applying the magnetic field 225 in the opposite direction (i.e., applying the magnetic field 225 to a top surface of the substrate 210), if desired.

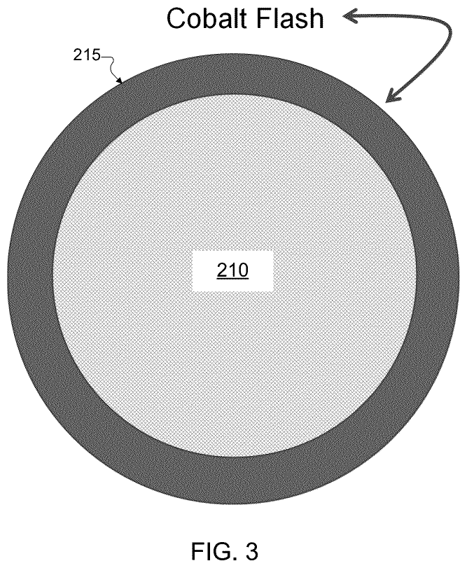

FIG. 3 illustrates additional details of the process 200 according to this disclosure. As shown in FIG. 3, the substrate 210 has a circular or annular shape, similar to the substrate 104 of FIG. 1. The bus bars 215 are formed of a thin layer of cobalt that is flashed or deposited onto the substrate 210.

Although FIGS. 1 through 3 illustrate an example viewing window 100, an example process 200 for selective magnetic adhesion of an EMI grid, and related details, various changes may be made to FIGS. 1 through 3. For example, instead of an EMI grid 205, the process 200 can be implemented with other types of grids or meshes. Such a mesh (or porous) screen material can be electrically conductive, non-conductive, or a combination, and can be composed of CNTs, or CNTs plus other materials in the form of powder or threads. In addition, various components shown and described above may be combined, further subdivided, replicated, rearranged, or omitted and additional components may be added according to particular needs. Also, while shown as a series of steps, various steps of the process 200 could overlap, occur in parallel, occur in a different order, or occur multiple times. Moreover, some steps could be combined or removed and additional steps could be added according to particular needs.

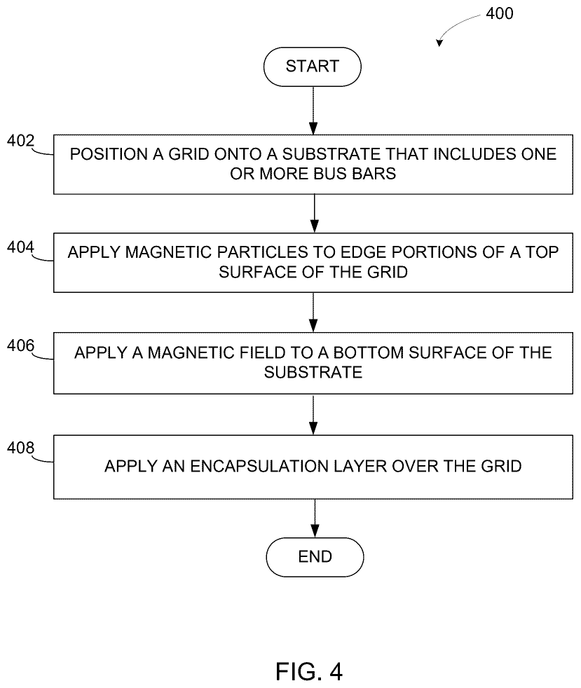

FIG. 4 illustrates an example method 400 for selective magnetic adhesion of an EMI grid according to this disclosure. For case of explanation, the method 400 is described as being performed using the process 200 of FIGS. 2A through 2D. However, the method 400 could be used with any other suitable device or system.

As shown in FIG. 4, at step 402, a grid is positioned onto a substrate that includes one or more bus bars on a top surface. This may include, for example, positioning the EMI grid 205 onto the substrate 210.

At step 404, magnetic particles are applied to edge portions of a top surface of the grid. This may include, for example, applying magnetic particles 220 to edge portions of the top surface of the EMI grid 205.

At step 406, a magnetic field is applied to a bottom surface of the substrate. The magnetic field attracts the magnetic particles downward toward the substrate. This may include, for example, the magnetic source 222 applying the magnetic field 225 to the bottom surface of the substrate 210.

At step 408, an encapsulation layer is applied over the grid while the magnetic field is applied to the bottom surface of the substrate. This may include, for example, applying the encapsulation layer 230 over the EMI grid 205 while the magnetic field 225 is applied to the bottom surface of the substrate 210.

Although FIG. 4 illustrates one example of a method 400 for selective magnetic adhesion of an EMI grid, various changes may be made to FIG. 4. For example, while shown as a series of steps, various steps shown in FIG. 4 could overlap, occur in parallel, occur in a different order, or occur multiple times. Moreover, some steps could be combined or removed and additional steps could be added according to particular needs.

In some embodiments, various functions described in this patent document are implemented or supported by a computer program that is formed from computer readable program code and that is embodied in a computer readable medium. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive (HDD), a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable storage device.

It may be advantageous to set forth definitions of certain words and phrases used throughout this patent document. The term “couple” and its derivatives refer to any direct or indirect communication between two or more components, whether or not those components are in physical contact with one another. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112 (f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112 (f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method comprising:
positioning a grid onto a substrate that includes one or more bus bars on a top surface of the substrate;
selectively applying magnetic particles to portions of a top surface of the grid;
applying a magnetic field to a bottom surface of the substrate, the magnetic field attracting the magnetic particles downward toward the substrate; and
applying an encapsulation layer over the grid while the magnetic field is applied to the bottom surface of the substrate.

2. The method of claim 1, wherein the grid comprises an electromagnetic interference (EMI) grid.

3. The method of claim 2, wherein the EMI grid is at least partially formed of carbon nanotubes (CNTs).

4. The method of claim 2, wherein the magnetic particles are applied to the portions of the top surface of the EMI grid over the one or more bus bars without being applied to other portions of the top surface.

5. The method of claim 4, wherein the other portions of the top surface include an optically transparent viewing area.

6. The method of claim 1, wherein the bus bars are electrically conductive and the substrate is electrically non-conductive.

7. The method of claim 1, wherein the substrate is annular.

8. The method of claim 1, further comprising:
applying the magnetic field to a top surface of the substrate to remove the grid without damaging the substrate.

9. The method of claim 1, wherein selectively applying the magnetic particles to portions of the top surface of the grid comprises applying the magnetic field to one of (i) edge portions of the substrate, or (ii) a set of locations on the substrate that promotes selective integration between the grid and the substrate at specific locations.

10. A system comprising:
a substrate;
one or more bus bars disposed on a top surface of the substrate;
a grid positioned on the substrate;
magnetic particles selectively applied to portions of a top surface of the grid;
a magnetic source configured to apply a magnetic field to a bottom surface of the substrate, the magnetic field configured to attract the magnetic particles downward toward the substrate; and
an encapsulation layer disposed over the grid and configured to be applied while the magnetic field is applied to the bottom surface of the substrate.

11. The system of claim 10, wherein the grid comprises an electromagnetic interference (EMI) grid.

12. The system of claim 11, wherein the EMI grid is at least partially formed of carbon nanotubes (CNTs).

13. The system of claim 11, wherein the magnetic particles are applied to the portions of the top surface of the EMI grid over the one or more bus bars without being applied to other portions of the top surface.

14. The system of claim 13, wherein the other portions of the top surface include an optically transparent viewing area.

15. The system of claim 10, wherein the bus bars are electrically conductive and the substrate is electrically non-conductive.

16. The system of claim 10, wherein the substrate is annular.

17. A method comprising:
positioning a grid onto an annular substrate that includes a beveled edge portion on a top surface;
selectively applying magnetic particles to portions of a top surface of the grid covering the beveled edge portion of the annular substrate;
applying a magnetic field to a bottom surface of the annular substrate, the magnetic field attracting the magnetic particles downward toward the annular substrate; and
applying an encapsulation layer over the grid while the magnetic field is applied to the bottom surface of the annular substrate.

18. The method of claim 17, wherein the grid comprises an electromagnetic interference (EMI) grid.

19. The method of claim 18, wherein the EMI grid is at least partially formed of carbon nanotubes (CNTs).

20. The method of claim 18, wherein the magnetic particles are applied to the portions of the top surface of the EMI grid without being applied to other portions of the top surface.
